(19) United States
(12) Patent Application Publication
(10) Pub. No.: US 2014/0261610 A1
(43) Pub. Date: Sep. 18, 2014

(54) SOLAR CELL MODULE WITH DUAL PURPOSE VAPOR BARRIER/BUSBAR

(71) Applicant: Eric Ng, Mountain View, CA (US)

(72) Inventor: Eric Ng, Mountain View, CA (US)

(73) Assignee: Nanosolar, Inc., San Jose, CA (US)

(21) Appl. No.: 13/799,060

(22) Filed: Mar. 13, 2013

(51) Int. Cl. H01L 31/048

(52) U.S. Cl. CPC H01L 31/0487
USPC 136/244; 136/256

(57) ABSTRACT

In a photovoltaic module, the solar cells and other necessary layers are placed on a backsheet with a multi-layer structure. A conductive part of a backsheet may provide a vapor barrier as well as replace busbars to route the circuit from one location of the module to another. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### FIELD OF THE DISCLOSURE

This invention relates generally to solar power systems. More particularly, it relates to apparatus and methods of photovoltaic or solar module design and fabrication.

### BACKGROUND OF THE INVENTION

Photovoltaic (PV) systems use solar panels to convert sunlight into electricity. Such a system typically includes an array of PV modules, an inverter and interconnection wiring. Each PV module has a plurality of PV cells electrically connected together, which produce direct current (DC) power. An inverter is provided to convert the collected power to a certain desired voltage or alternating current (AC). A thin strip of copper or aluminum between cells, called a busbar, is provided to conduct the direct current collected from the cells to the inverter. More specifically, a dedicated busbar is provided to route the circuit from one location of the module to another. It is typically routed behind or outside the cell array, and electrically isolated by materials, such as polyethylene terephthalate (PET).

For some PV modules, the array of cells and other necessary layers are formed on an aluminum based laminate as a module backsheet. The backsheet is the outermost layer of the PV module to protect the inner components of the module, specifically the PV cells and electrical components. In particular, the backsheet may provide physical protection from damage, moisture, water ingress and UV degradation, and also provide electrical insulation and long-term unit stability.

### BRIEF DESCRIPTION OF THE DRAWINGS

FIG. 1 is a cross-sectional view of a portion of a solar module of present disclosure; and

FIG. 2A is a partially exploded cross-sectional view of a solar module of present disclosure.

FIG. 2B is a partially exploded three-dimensional view of a solar module of present disclosure.

FIG. 3 is a cross-sectional view of an example of a solar cell that may be used in a solar module of the type described in the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the aspects of the present disclosure described below are set forth without any loss of generality to, and without imposing limitations upon, the claims that follow this description.

In this specification and the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and thus, the description includes both structures wherein a device possesses the anti-reflective film feature and structures wherein the anti-reflective film feature is not present.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . . .

The present disclosure describes the usage of a conductive part of a backsheet as a way to provide a vapor barrier and replace a dedicated busbar. This simplifies the materials for the manufacturing process as well as it would spread the resistive heat across a larger surface to keep the bus cool.

FIG. 1 shows a not-to-scale cross-sectional view of a part of a solar module 100. The solar module 100 of the present disclosure may include a top layer 110, a top encapsulant layer 120, an array of solar cells 130, a bottom encapsulant layer 140, a backsheet 150 and tabs 160a and 160b.

The top layer 110 is a transparent layer. By way of non-limiting example, the top layer 110 may be made of a plastic barrier film such as a 3M™ UBF-9L and 510. In another example, the top layer 110 may also be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. The thickness of the top layer 110 may be in the range of about 0.1 mm to about 4.0 mm.

The top encapsulant layer 120 may include any of a variety of pottant materials, such as but not limited to Tefzel®, polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the top encapsulant layer 120 may be in the range of about 400 μm or thinner. Optionally, some embodiments may have more than two encapsulant layers and some may have only one encapsulant layer (either layer 120 or 140).

It should be understood that the module 100 is not limited to any particular type of solar cell. The array of solar cells 130 includes a plurality of solar cells which may be silicon-based or non-silicon based solar cells. By way of non-limiting example, the solar cells may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano particles, or quantum dots.

Similar to the top encapsulant layer 120, the bottom encapsulant layer 140 may be any of a variety of pottant materials, such as but not limited to Tefzel®, polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous PET, urethane acrylic, acrylic, other fluoroelastomers, other materials of similar qualities, or combinations thereof. The thickness of the bottom encapsulant layer 140 may be in the range of about 400 μm or thinner.

The backsheet 150 provides protective qualities to the underside of the module 100. The backsheet 150 may be a multi-layer structure that provides a vapor barrier, an interface for adhesive used for attachment of the module 100 to a structure, such as a roof, and protection from physical damage and external stress. By way of non-limiting example, the backsheet 150 may be a multi-layer structure such as 3M™ Scotchshield™ film 15T or 17T, or Coveme dyMat PYE-3000. As seen in FIG. 1, the backsheet structure 150 may be comprised of dielectric layers 152 and 156 and a support layer 154 sandwiched between the dielectric layers 152 and 156. The dielectric layer 152 or 156 may be made of any electrically insulating materials such as polyethylene terephthalate, or alumina. The thickness of the dielectric layer 152 or 156 may be in the range of about [20 um to 100 um]. One of the dielectric layers 152 or 156 may be optionally removed. Optionally, another protective layer may be applied to the dielectric layer for improvement on the voltage, fill pores/cracks, and/or alter the surface properties of the layer that is dip coated, spray coated, or otherwise thinly deposited on the dielectric layer. Optionally, the protective layer may be comprised of a polymer such as but not limited to fluorocarbon coating, perfluoro-octanoic acid based coating, or neutral polar end group, fluoro-oligomer or fluoropolymer. Optionally, the protective layer may be comprised of a silicon based coating such as but not limited to polydimethyl siloxane with carboxylic acid or neutral polar end group, silicone oligomers, or silicone polymers.

The support layer 154 may be made of an electrically conductive material, such as aluminum foil, that may provide vapor barrier for the module 100. With its conductivity characteristic property, the support layer 154 may readily integrate with busbars or other electrical connections to route a circuit via the support layer 154 from one location of the module to another. The support layer may similarly be used to electrically connect a solar cell in another module and/or an electrical lead from another module to create an electrical interconnection between modules. Busbars or other electrical connections may be electrically isolated by electrically insulating materials such as PET, EVA and/or combinations thereof.

One or more tabs 160 may provide electrical connections between the support layer 154 and an electrical wire leading to cells in another modules or an inverter that is part of the module 100.

One or more conductive tab 160 may be coupled to the support layer 154 by welded connection or soldering. Materials of tabs 160 may be any conductive materials, such as aluminum or copper. Optionally, a seal may be applied around to the backsheet as strain relief and surround the connection between the tabs 160 and the layer 154. The seal may be comprised of one or more of the following materials such as but not limited to desiccant loaded versions of EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities or combinations thereof.

FIGS. 2A-2B show one example of the wire connections in the module 100 in accordance with the present disclosure. In particular, the support layer 154 may be electrically connected with a last cell 130b in a series through the bottom encapsulant 140 and dielectric layer 152 by a vertical electrical connection 210. The support layer 154 may then act as a busbar to run an electrical connection from the last cell 130b. Optionally, the sidewalls of the openings in the bottom encapsulant layer 140 and in the dielectric layer 152 may have insulating layers that prevent electrical contact with the vertical connection 210. Optionally, the vertical electrical connection 210 may have a coating or layer to electrically insulate it from the bottom encapsulant layer 140 and the dielectric layer 152.

As seen in FIG. 2B, the conductive tab 160 may be located along any edge of the support layer 154 and may protrude from the rest of the backsheet structure 150 to provide a desired electrical connection. In some implementations, the support layer may be pre-fabricated with the tab integral to the support layer. The support layer may be laminated between the dielectric layers 152 and 156 in such a way that the tab 160 protrudes from the edge of the backsheet 150. Optionally, it may have multiple exit points from the cell string for connection to the conductive support layer 154 when necessary. Tabs 160 may be connected to the conductive support layer 154 as shown in FIG. 2 in a side-ways orientation with respect to an incoming connection 132 to a first cell 130a in the series. Alternatively, one or more tabs 160 may be connected to the support layer 154 from an underside orientation through dielectric layer 156 (not shown).

Solar cell modules of the type described herein may incorporate any suitable type of photovoltaic device within solar cells 130. One example, among others of a suitable photovoltaic device 350 is shown in FIG. 3. The device 350 includes a base substrate 352, an optional adhesion layer 353, a base or back electrode 354, a p-type absorber layer 356 incorporating a film of the type described above, an n-type semiconductor thin film 358 and a transparent electrode 360.

By way of example, the base substrate 352 may be made of a metal foil, a polymer such as polyimides (PI), polyamides, polyetheretherketone (PEEK), Polyethersulfone (PES), polyetherimide (PEI), polyethylene naphtalate (PEN), Polyester (PET), related polymers, a metallized plastic, and/or combination of the above and/or similar materials. By way of nonlimiting example, related polymers include those with similar structural and/or functional properties and/or material attributes. The base electrode 354 is made of an electrically conductive material. By way of example, the base electrode 354 may be of a metal layer whose thickness may be selected from the range of about 0.1 micron to about 25 microns. An optional intermediate layer 353 may be incorporated between the electrode 354 and the substrate 352.

Optionally, a diffusion barrier layer 351 (shown in phantom) may be on the underside of substrate 352 and be comprised of a material such as but not limited to chromium, vanadium, tungsten, or compounds such as nitrides (including tantalum nitride, tungsten nitride, titanium nitride, silicon nitride, zirconium nitride, and/or hafnium nitride), oxides (including alumina, Al₂O₃, SiO₂, or similar oxides), carbides (including SiC), and/or any single or multiple combination of the foregoing.

The transparent electrode 360 may include a transparent conductive layer 359 and a layer of metal (e.g., Al, Ag, Cu, or Ni) fingers 361 to reduce sheet resistance. Optionally, the layer 353 may be a diffusion barrier layer to prevent diffusion of material between the substrate 352 and the electrode 354. The diffusion barrier layer 353 may be a conductive layer or it may be an electrically nonconductive layer. As nonlimiting examples, the layer 353 may be composed of any of a variety of materials, including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. Although not limited to the following, the thickness of this layer can range from 10 nm to 50 nm. In some embodiments, the layer may be from 10 nm to 30 nm. Optionally, an interfacial layer may be located above the electrode 354 and be comprised of a material such as including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing.

By way of example, the absorber layer may include copper-indium-gallium-selenium (for a CIGS-type photovoltaic device), CdSe, CdTe, Cu(In,Ga)(S,Se)₂, Cu(In,Ga,Al)(S,Se,Te)₂, and/or combinations of the above, where the active materials may be present in any of several forms including but not limited to bulk materials, micro-particles, nano particles, or quantum dots. Examples of fabrication of such films are described, e.g., in U.S. Patent Application Publication Number 2012/0313200 published on Dec. 13, 2012, the entire disclosures of which are incorporated herein by reference.

The n-type semiconductor thin film 358 serves as a junction partner between the compound film and the transparent conducting layer 359. By way of example, the n-type semiconductor thin film 358 (sometimes referred to as a junction partner layer) may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also be configured for use in a continuous roll-to-roll and/or segmented roll-to-roll and/or a batch mode system.

The transparent conductive layer 359 may be inorganic, e.g., a transparent conductive oxide (TCO) such as but not limited to indium tin oxide (ITO), fluorinated indium tin oxide, zinc oxide (ZnO) or aluminum doped zinc oxide, or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive layer may include a transparent conductive polymeric layer, e.g. a transparent layer of doped PEDOT (Poly-3,4-Ethylenedioxythiophene), carbon nanotubes or related structures, or other transparent organic materials, either singly or in combination, which can be deposited using spin, dip, or spray coating, and the like or using any of various vapor deposition techniques. Optionally, it should be understood that intrinsic (non-conductive) i-ZnO or other intrinsic transparent oxide may be used between CdS and Al-doped ZnO. Combinations of inorganic and organic materials can also be used to form a hybrid transparent conductive layer. Thus, the layer 359 may optionally be an organic (polymeric or a mixed polymeric-molecular) or a hybrid (organic-inorganic) material. Examples of such a transparent conductive layer are described e.g., in commonly-assigned US Patent Application Publication Number 20040187317, which is incorporated herein by reference.

It is noted that although a thin film CIGS-type photovoltaic device is depicted in FIG. 3, those skilled in the art will recognize that solar modules in accordance with aspects of the present disclosure may incorporate other types of solar cells such as silicon-based solar cells.

While the above is a complete description of the preferred embodiment of the present invention, it is possible to use various alternatives, modifications and equivalents. Any feature described herein, whether preferred or not, may be combined with any other feature described herein, whether preferred or not.

What is claimed is:

1. An apparatus, comprising:
a solar cell module having one or more solar cells; and
a backsheet having an electrically conductive support layer sandwiched between first and second insulating layers, wherein the solar cell module is attached to one of the insulating layers of the backsheet,
wherein the support layer is in electrical contact with an electrode layer of at least one solar cell in the solar cell module, wherein the support layer routes a circuit from one location of the solar cell module to another.

2. The apparatus of claim 1, wherein the support layer includes a layer of aluminum foil.

3. The apparatus of claim 1, wherein the support layer is configured to electrically connect a solar cell in another module and/or an electrical lead from another module to create an electrical interconnection between the solar cell module and the other module.

4. The apparatus of claim 1, further comprising one or more electrically conductive tabs configured to provide electrical connections between the support layer and an electrical wire leading to cells in another modules or an inverter.

5. The apparatus of claim 4, wherein the one or more electrically conductive tabs are coupled to the support layer by welded connection or soldering.

6. The apparatus of claim 4, wherein the one or more electrically conductive tabs are made of aluminum or copper.

7. The apparatus of claim 4, further comprising a seal applied around to the backsheet and surrounding a connection between the one or more electrically tabs and the support layer.

8. The apparatus of claim 1, wherein the one or more solar cells include a plurality of solar cells electrically connected in series.

9. The apparatus of claim 1, wherein the one or more solar cells include a base substrate, a back electrode, an absorber layer of a first semiconductor type, an semiconductor film of a second semiconductor type that is opposite the first semiconductor type and a transparent electrode, wherein the base substrate is between the backsheet and the back electrode, the absorber layer is between the back electrode and the semiconductor film, wherein the semiconductor film is between the absorber layer and the transparent electrode and acts as a junction partner between the absorber layer and the transparent electrode.
